(19) United States
(12) Patent Application Publication
(10) Pub. No.: US 2004/0196060 A1
(43) Pub. Date: Oct. 7, 2004

(54) Method of identifying physical mapping of IC products

(75) Inventors: Cheng-Piao Lin, Hsinchu (TW); Cheng-Chun Ting, Hsinchu (TW)

Correspondence Address: Richard L. Byrne, 700 Koppers Building, 436 Seventh Avenue, Pittsburgh, PA, 15219-1818, US

(73) Assignee: TAIWAN SEMICONDUCTOR MANUFACTURING CO., LTD.

(21) Appl. No.: 10/406,680

(22) Filed: Apr. 3, 2003

(51) Int. Cl. G01R 31/26

(52) U.S. Cl. 324/765

(57) ABSTRACT

A method to identify physical mapping of IC products is described. First, a tester is used to exert a stress at a specific address of a chip, so as to generate light, thermal or current variation in an electronic device of the chip. Then, a detecting apparatus is used to detect the chip, for obtaining the actual position of electronic device generating the variation. A photoemission microscope can be used to detect light variation in the chip, a thermal emission microscope can be used to detect thermal variation in the chip, and a superconducting quantum interference device can be used to detect current variation in the chip.

### FIELD OF THE INVENTION

The present invention relates to method of analyzing integrated circuit (IC) products. More particularly, the present invention relates to a method of identifying physical mappings of IC products.

### BACKGROUND OF THE INVENTION

The process of fabricating an integrated circuit includes material preparation, circuit fabrication, wafer-probe testing, assembly, final testing, and shipment. Initially, a silicon ingot is cut to create individual wafers, and circuit fabrication is performed. The circuit fabrication may include several subsequent steps of diffusion, ion implantation, photolithography and etching. Typical process steps comprise deposition and growth of a thin film on the surface of a wafer, transferring the circuit pattern to a masking layer on the film, removing areas of the film not protected by the masking layer and doping exposed areas of the wafer.

Along with continuing evolution in semiconductor integrated circuit designs and manufacturing techniques, great progress has been made over the past generation in all phases of integrated manufacturing in the reliability of the finished products. Reliability of integrated circuit is of paramount importance to all concerned. The relentless push toward higher levels of integration, while maintaining high levels of reliability, presents an ongoing challenge. Part of the integrated circuit manufacturer's quest to improve reliability involves failure analysis—the analysis of failed parts in order to determine what caused the failure. Most manufacturers maintain a failure analysis (FA) department, staffed by engineers and other professionals who are skilled in this specialty.

Integrated circuits comprise thousands of solid electronic devices, and theses electronic devices are reduced and manufactured in an area small than 2 cm². After a failure analysis of a chip is performed, an address is obtained as a result. The address represents which electric device in the chip has failed, and is called an ‘electrical address’. The electrical address of failed electronic device is known, but the actual location or structure of the failed electronic device on the chip, called a ‘physical address’, is unknown. Therefore, one job of an FA department is to obtain the electrical address of a failed chip from a tester and find out the physical address in the chip, so that the manufacturing processes can be adjusted to eliminate the cause of the failure.

The step of finding a corresponding physical address for an electrical address is called ‘physical mapping’, and is performed before or after a failure analysis. Currently, a laser cutter is often used to identify the physical mapping of an IC product. First, the laser cutter is used to damage a specific area of an IC chip, causing failure of the specific area, where the specific area is one physical address decided by an operator. Then, a tester is used to test the chip. The testing result reveals the electrical address of the failure on the chip. The physical mapping is completed by repeating the aforementioned steps.

However, using the laser cutter has some disadvantages. The method of using laser cutter to perform a physical mapping is a destructive method, so that many IC chips are consumed in the test and not used anymore. Further, the area damaged by the laser cutter is not easily controlled, and consequently provides only rough data for the physical mapping.

### SUMMARY OF THE INVENTION

In view of the foregoing disadvantages, it is therefore an objective of the present invention to provide an improved method to physically map IC products. A tester is connected with a detecting apparatus. The test is used to stress an electronic device of an IC chip, so that the electronic device generates a variation. Then, the detecting apparatus is used to find the variation of the IC chip, so that the actual location of the electronic device is obtained. Repeating the aforementioned steps identifies the corresponding relation between the electrical addresses and the physical addresses.

In accordance with the foregoing objective of the present invention, a method to identify physical mapping of IC products comprises the following: first, an electrical address of an IC chip is chosen; next, a tester is used to stress the electrical address, so as to produce a variation in an electronic device on the IC chip; then, a detecting apparatus is used to detect the location of the electronic device with the variation; and finally, an actual position corresponding to the electrical address is obtained.

In a preferred embodiment of the present invention, the tester is connected with a photoemission microscope. First, the test stresses a memory to emit light at an electronic address. Then, the photoemission microscope is used to find the emitting spot of the memory. A physical address in the memory corresponding to the electrical address is consequently obtained.

In conclusion, the present invention has many advantages, including: (1) it is a non-destructive method; (2) fewer chips are used for testing; (3) the addresses decided by operators are controllable; and (4) the obtained physical mapping is more detailed.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic diagram showing the apparatuses used to physically map, according to one preferred embodiment of the present invention; and

FIG. 2 is a flowchart showing one preferred embodiment using the method of physical mapping, according the present invention.

### DETAILED DESCRIPTION OF THE PREFERRED EMBODIMENT

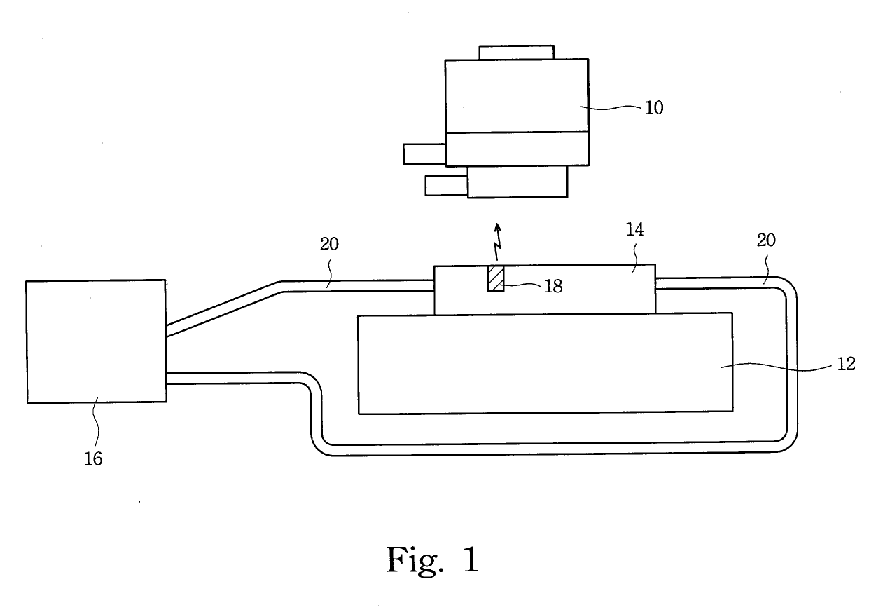

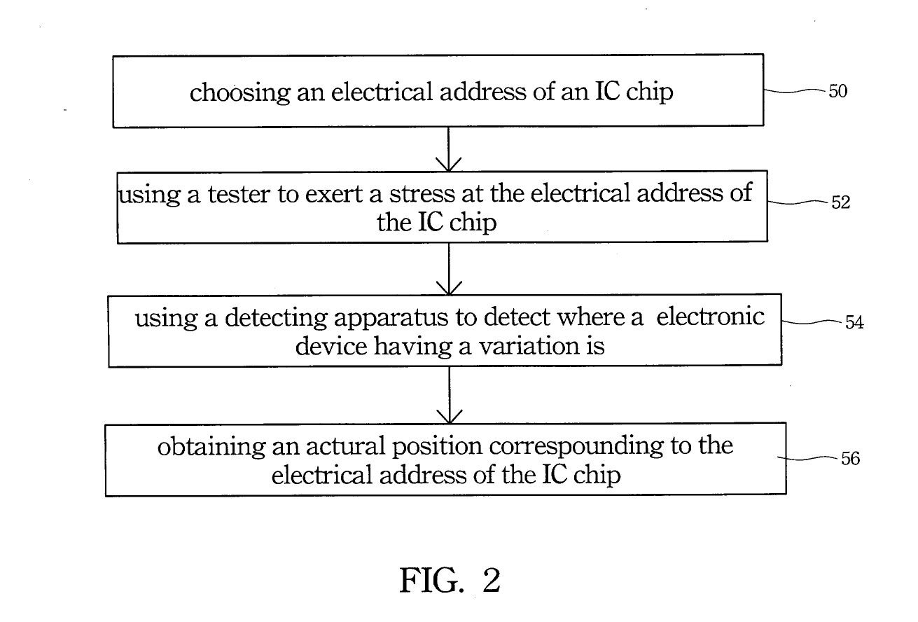

The present invention discloses a method of physical mapping. Reference is made to FIG. 1 and FIG. 2, in which FIG. 1 illustrates a schematic diagram showing the apparatuses used in the physical mapping, and FIG. 2 is a flowchart showing the method of physical mapping.

Referring to FIG. 1, the equipment used to perform the physical mapping according to the present invention includes a detecting apparatus 10. Chip 14 is situated on a holder 12 of the detecting apparatus 10, and the variations of chip 14 are detected by the detecting apparatus 10 thereon. For example, generally, a photoemission microscope is used to detect light emitting variations in a chip, a thermal emission microscope is used to detect thermal variations in a chip, and a superconducting quantum interference device (SQUID) is used to detect electricity variations in a chip.

Besides the detecting apparatus, the equipment of the present invention includes a tester 16. The tester 16 is connected with the chip 14 by electric wires 20, and operators can command tester 16 to conduct circuits of the chip 14. IC products are divided into logic products and memory products, and different testers respectively test their different functions. In the test process of the chip 14 by the tester 16, first, an electric current is conducted to the chip 14. In a conventional process, if part of the chip 14 fails, the tester 16 shows the electrical address of the failed parts of the chip 14. However, the present invention does not perform these steps.

Referring simultaneously to FIG. 1 and FIG. 2, the method of physical mapping is described. First, step 50 is performed and an electrical address of an IC chip 14 is chosen. Next, in step 52, a tester 16 exerts a stress at an electrical address of the IC chip 14 and induces one electronic device 18 indicated by the electrical address to generate a variation. The electronic device 18 can generate light, heat or current, according to different testers.

Then, step 54 is performed, in which a detecting apparatus 10 detects where the electronic device 18 with the variation is. According to the different variations, different detecting apparatuses 10, like a photoemission microscope, a thermal emission microscope, or a SQUID, can be used. Finally, in step 56, an actual position of the electronic device 18 in the chip 14 is obtained. By repeating the aforementioned steps, the corresponding relation between the electrical address and the actual position of the chip 14 is completed.

In one preferred embodiment of the present invention, the equipment of the present invention includes a photoemission microscope and a Mosaid 3490 tester to perform the method of physical mapping of a memory.

First, an address of a memory is selected, for example, X=0. Next, the Mosaid 3490 tester is used to exert stress at the X=0 address of the memory. As a result of stressing, in a turn-on condition, electron-hole pairs are generated and recombined at the X=0 address of the memory. Therefore, due to the recombination of the electron-hole pairs, energy is released so that light is generated at the X=0 address of the memory. Later, a photoemission microscope is used to detect where the emission spot is, so that the actual position of the X=0 address is obtained.

By changing the selected address, for example, X=1, 2, 3, . . . , and repeating the foregoing steps, the actual position of all addresses of the memory are obtained. The characteristic of the aforementioned preferred embodiment of the present invention is that, through stressing at a chip by a tester, a light variation is generated at an electronic device of the chip. Therefore, a photoemission microscope can be used to detect the emission spot. Alternatively, , a tester collated with thermal emission microscope or a SQUID can be used to perform physical mapping by detecting thermal or current variation of the chip, respectively.

The present invention has advantages of convenience and detail, no matter whether applied to chips in the manufacturing process or chips returned by clients. When applied to chips in the manufacturing processes, the present invention is advantageously non-destructive, so that after checking the mapping manufacturing can proceed. Alternatively, when applied to a chip returned by a client, the present invention can check the corresponding relation data between the electrical addresses and the physical addresses of the chips. If the correct corresponding relation data is obtained, then the follow-up failure analysis is performed.

The present invention can obtain more detailed corresponding relation data between the electrical addresses and the physical addresses of an IC chip, and save many chips which would have been damaged in the conventional physical mapping processAs is understood by a person skilled in the art, the foregoing preferred embodiment of the present invention is illustrative rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A method of identifying a physical mapping of an integrated circuit (IC) product, the method comprising:
choosing an electrical address of an IC chip;
using a tester to exert a stress at the electrical address, so as to produce a variation in an electronic device in the IC chip;
using a detecting apparatus to detect where the electronic device having the variation is; and
obtaining an actual position corresponding to the electrical address.

2. The method of identifying a physical mapping of an IC product according to claim 1, wherein the variation is generation of light.

3. The method of identifying a physical mapping of an IC product according to claim 2, wherein the detecting apparatus is a photoemission microscope.

4. The method of identifying a physical mapping of an IC product according to claim 1, wherein the variation is generation of heat.

5. The method of identifying a physical mapping of an IC product according to claim 4, wherein the detecting apparatus is a thermal emission microscope.

6. The method of identifying a physical mapping of an IC product according to claim 1, wherein the variation is generation of electricity.

7. The method of identifying a physical mapping of an IC product according to claim 6, wherein the detecting apparatus is a superconducting quantum interference device (SQUID).

8. A method of identifying physical mapping of a memory, the method comprising:
choosing an electrical address of a memory;
using a tester to exert a stress at the electrical address, so as to produce a variation at the electrical address of the memory;
using a detecting apparatus to detect where the electrical address having the variation is; and
obtaining a physical position corresponding to the electrical address.

9. The method of identifying a physical mapping of a memory according to claim 8, wherein the variation is generation of light.

10. The method of identifying a physical mapping of a memory according to claim 9, wherein the detecting apparatus is a photoemission microscope.

11. The method of identifying a physical mapping of a memory according to claim 8, wherein the variation is generation of heat.

12. The method of identifying a physical mapping of a memory according to claim 11, wherein the detecting apparatus is a thermal emission microscope.

13. The method of identifying a physical mapping of a memory according to claim 8, wherein the variation is generation of electricity.

14. The method of identifying a physical mapping of a memory according to claim 13, wherein the detecting apparatus is a superconducting quantum interference device.

15. A method of identifying a physical mapping of a memory, the method comprising:
choosing an electrical address of a memory;
using a tester to exert a stress at the electrical address, so as to generate light at the electrical address in the memory;
using a photoemission microscope to detect where the electrical address having the variation is; and
obtaining a physical position corresponding to the electrical address of the memory.
